(19) United States
(12) Patent Application Publication
(10) Pub. No.: US 2024/0047343 A1
(43) Pub. Date: Feb. 8, 2024

(54) SEMICONDUCTOR DEVICE, SEMICONDUCTOR SUBSTRATE AND MANUFACTURING METHOD THEREOF

(71) Applicant: nD-HI Technologies Lab,Inc., Taipei City (TW)

(72) Inventor: Ho-Ming TONG, Taipei City (TW)

(21) Appl. No.: 18/091,300

(22) Filed: Dec. 29, 2022

Related U.S. Application Data
(60) Provisional application No. 63/394,318, filed on Aug. 2, 2022.

(51) Int. Cl. H01L 23/522; H01L 23/498; H01L 23/00; H01L 21/324; H01L 21/02

(52) U.S. Cl. CPC H01L 23/5226; H01L 23/49838; H01L 24/03; H01L 24/05; H01L 24/08; H01L 21/324; H01L 21/0234; H01L 21/02052; H01L 2224/0381; H01L 2224/0217; H01L 2224/05009; H01L 2224/05022; H01L 2224/08146

(57) ABSTRACT

A semiconductor device includes a first semiconductor substrate and a second semiconductor substrate. The first semiconductor substrate includes a first base, a first bonding layer and a first conductive contact. The first bonding layer has a first through via. The first conductive contact is formed within the first through via. The second semiconductor substrate includes a second base, a second bonding layer and a second conductive contact. The second bonding layer has a second through via. The second conductive contact is formed within the second through via. The first conductive contact is electrically connected to the second conductive contact, and the first bonding layer and the second bonding layer are in direct contact with each other.

This application claims the benefit of U.S. Provisional application Ser. No. 63/394,318, filed Aug. 2, 2022, the disclosure of which is incorporated by reference herein in its entirety.

### FIELD OF THE INVENTION

The invention relates to a semiconductor device, a semiconductor substrate and a manufacturing method thereof, and more particularly to a semiconductor device including two semiconductor substrates, a semiconductor substrate and a manufacturing method thereof.

### BACKGROUND OF THE INVENTION

Since it dawned on the microelectronics industry in the 1960s, flip chip has elevated itself to become the premier interconnect technology which has enabled advanced ICs (integrated circuits) and advanced SiPs (system-in-a-packages) embodying advanced ICs to continue to scale with ever-higher complexities and ever-finer interconnect pitches. In the past six decades or so, flip chip solder connections has progressed from relying solely on traditional and coarser-pitch lead containing solder bumps to lead-free solder bumps and finer-pitch copper pillar micro-bumps. Today's most advanced flip chip employs 40 μm micro-bump pitches with about 20 μm bump sizes and about 20 μm spacing. Extending beyond the 40 μm pitches is crucial in order for the semiconductor industry to extract maximal performance from advanced logic devices (e.g., high-end processors) and advanced memory devices (e.g., high-bandwidth memory DRAM) through product miniaturization.

### SUMMARY OF THE INVENTION

In an embodiment of the invention, a semiconductor device is provided. The semiconductor device includes a first semiconductor substrate and a second semiconductor substrate. The first semiconductor substrate includes a first base, a first bonding layer and a first conductive contact. The first bonding layer has a first through via. The first conductive contact is formed within the first through via. The second semiconductor substrate includes a second base, a second bonding layer and a second conductive contact. The second bonding layer has a second through via. The second conductive contact is formed within the second through via. The first conductive contact is electrically connected to the second conductive contact with the first bonding layer and the second bonding layer being in direct contact with each other.

In another embodiment of the invention, a semiconductor substrate is provided. The semiconductor substrate includes a base, a bonding layer and a conductive contact. The bonding layer has a bonding surface and a through via extending from the bonding surface. The conductive contact is formed within the through via and recessed with respect to the bonding surface. The bonding surface is a planarized surface.

In another embodiment of the invention, a manufacturing method of a semiconductor device includes the following steps: preparing a first semiconductor substrate, including: forming a first bonding layer over a first base, wherein the first bonding layer has a first through via; and forming a first conductive contact within the first through via; preparing a second semiconductor substrate, including: forming a second bonding layer over a second base, wherein the second bonding layer has a second through via; and forming a second conductive contact within the second through via; and the first bonding layer and the second bonding layer being in direct contact with each other.

Numerous objects, features and advantages of the invention will be readily apparent upon a reading of the following detailed description of embodiments of the invention when taken in conjunction with the accompanying drawings. However, the drawings employed herein are for the purpose of descriptions and should not be regarded as limiting.

### BRIEF DESCRIPTION OF THE DRAWINGS

The Above Objects and Advantages of the Invention Will Become More Readily Apparent to Those Ordinarily Skilled in the Art after Reviewing the Following Detailed Description and Accompanying Drawings, in which:

FIG. 1 illustrates a schematic diagram of a cross-sectional view of a semiconductor device according to an embodiment of the invention;

FIG. 2 illustrates a schematic diagram of a cross-sectional view of a semiconductor device according to an embodiment of the invention;

FIG. 3 illustrates a schematic diagram of a cross-sectional view of a semiconductor device according to an embodiment of the invention;

FIG. 4 illustrates a schematic diagram of a cross-sectional view of a semiconductor device according to an embodiment of the invention;

FIG. 5 illustrates a schematic diagram of a cross-sectional view of a semiconductor device according to an embodiment of the invention;

FIGS. 6A to 6L illustrate schematic diagrams of a manufacturing method of the semiconductor device of FIG. 1;

FIGS. 7A to 7M illustrate schematic diagrams of a manufacturing method of the semiconductor device of FIG. 2;

FIGS. 8A to 8C illustrate schematic diagrams of a manufacturing method of the semiconductor device of FIG. 3;

FIGS. 9A to 9B illustrate schematic diagrams of a manufacturing method of the semiconductor device of FIG. 4; and

FIGS. 10A to 100 illustrate schematic diagrams of a manufacturing method of the semiconductor device of FIG. 5.

### DETAILED DESCRIPTION OF PREFERRED EMBODIMENTS

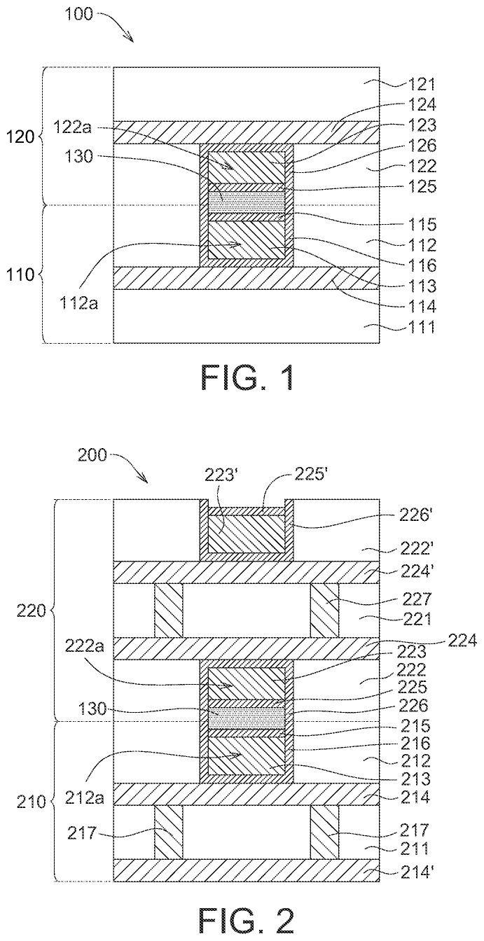

Referring to FIG. 1, FIG. 1 illustrates a schematic diagram of a cross-sectional view of a semiconductor device 100 according to an embodiment of the invention. The semiconductor device 100 includes a first semiconductor substrate 110, a second semiconductor substrate 120 and at least one solder 130. The first semiconductor substrate 110 includes a first base 111, a first bonding layer 112, at least one first conductive contact 113, a first patterned-conductive layer 114, a first conductive layer 115 and a first barrier/seed layer 116. The first bonding layer 112 has at least one first through via 112a. The first conductive contact 113 is formed within the first through via 112a. The second semiconductor substrate 120 includes a second base 121, a second bonding layer 122, at least one second conductive contact 123, a second patterned-conductive layer 124, a second conductive layer 125 and a second barrier/seed layer 126. The second bonding layer 122 has at least one second through via 122a. The second conductive contact 123 is formed within the second through via 122a. The first conductive contact 113 is electrically connected to the second conductive contact 123, and the first bonding layer 112 and the second bonding layer 122 are in direct contact with each other.

As illustrated in FIG. 1, in the present embodiment, the first semiconductor substrate 110 and the second semiconductor substrate 120 are directly connected by the bonding layers without any adhesive layer or intermediate layer. Due to the first bonding layer 112 and the second bonding layer 122 being in direct contact with each other, there is no adhesive layer between the first bonding layer 112 and the second bonding layer 122. In addition, Due to the first bonding layer 112 and the second bonding layer 122 being in direct contact with each other, there is no obvious interface (illustrated in dotted point) between the first bonding layer 112 and the second bonding layer 122 after bonding (or heating). In an embodiment, the first bonding layer 112 and the second bonding layer 122 are formed of the same material, for example, dielectric material, such as silicon dioxide (SiO₂) or polyimide (PI).

In the present embodiment, the first semiconductor substrate 110 and the second semiconductor substrate 120 may be automatically aligned through van der Waals bonds formed between water molecules and silanol groups at the two opposing oxide surfaces which are created by surface pre-conditioning using, for example, plasma and water wetting.

As illustrated in FIG. 1, for first semiconductor substrate 110, the first base 111 is silicon base, for example, a portion of a silicon wafer. The first bonding layer 112 is formed over the first patterned-conductive layer 114. The first patterned-conductive layer 114 is formed over the first base 111 and exposed from the first through via 112a. The first through via 112a may be formed using, for example, photolithography, etching, laser ablation, etc. The first patterned-conductive layer 114 includes, for example, a redistribution layer (RDL), a back-end-of-the-line (BEOL) layer or combination thereof. The first conductive layer 115 is formed on the first conductive contact 113. The first conductive layer 115 is a multi-layered (barrier layer plus bonding layer) structure, for example, Ni/Au layers or Ni/Pd/Au layers. Other barrier/bonding layer options can include Ti/Ni—V/Au, Ti/Ni/Ag, Ti/Ag, Ti/Au, Ti/Ni/Au, Ti/Ni—V/Au, Ti/Ni—V/Ag and Ti/Ti—W/Au. In another embodiment, the first conductive layer 115 can be a single-layered (barrier layer) structure, for example, Ni layer. The first conductive layer 115 is formed by using, for example, plating, physical vapor deposition, chemical vapor deposition/atomic layer deposition, etc. The first barrier/seed layer 116 is formed within the first through via 112a. Furthermore, the first barrier/seed layer 116 is formed on an inner sidewall of the first through via 112a. The first barrier/seed layer 116 is multi-layered structure, for example, Ti/Cu layers, TiN/Cu layers, Ta/Cu layers or TaN/Cu layers.

As illustrated in FIG. 1, for second semiconductor substrate 120, the second base 121 is silicon base, for example, a portion of a silicon wafer. The second bonding layer 122 is formed over the second patterned-conductive layer 124. The second through via 122a may be formed using, for example, photolithography, etching, laser ablation, etc. The second patterned-conductive layer 124 is formed over the second base 121 and exposed from the second through via 122a. The second patterned-conductive layer 124 is, for example, a RDL, a BEOL layer or combination thereof. The second conductive layer 125 is formed on the second conductive contact 123. The second conductive layer 125 is a multi-layered structure, for example, Ni/Au layers or Ni/Pd/Au layers. In another embodiment, the second conductive layer 125 is a single-layered structure, for example, Ni layer. The second conductive layer 125 is formed using, for example, plating, vapor deposition, etc. The second barrier/seed layer 126 is formed within the second through via 122a. Furthermore, the second barrier/seed layer 126 is formed on an inner sidewall of the second through via 122a. The second barrier/seed layer 126 is multi-layered structure, for example, Ti/Cu layers, TiN/Cu layers, Ta/Cu layers or TaN/Cu layers.

Referring to FIG. 2, FIG. 2 illustrates a schematic diagram of a cross-sectional view of a semiconductor device 200 according to an embodiment of the invention. The semiconductor device 200 includes a first semiconductor substrate 210, a second semiconductor substrate 220 and at least one solder 130 (e.g., In, Cu/Sn, Sn, Sn—Ag, Sn—Ag—Cu, or Sn—Bi).

As illustrated in FIG. 2, the first semiconductor substrate 210 includes a first base 211, a first bonding layer 212, at least one first conductive contact 213, a first patterned-conductive layer 214, a first patterned-conductive layer 214′, a first conductive layer 215, a first barrier/seed layer 216 and at least one first conductive via 217. The first bonding layer 212 has at least one first through via 212a. The first conductive contact 213 is formed within the first through via 212a.

As illustrated in FIG. 2, the second semiconductor substrate 220 includes a second base 221, a second bonding layer 222, at least one second conductive contact 223, a second patterned-conductive layer 224, a second conductive layer 225, a second barrier/seed layer 226, a second bonding layer 222′, at least one second conductive contact 223′, a second patterned-conductive layer 224′, a second conductive layer 225′, a second barrier/seed layer 226′ and at least one second conductive via 227. The second bonding layer 222 has at least one second through via 222a. The second conductive contact 223 is formed within the second through via 222a. The first conductive contact 213 is electrically connected to the second conductive contact 223, and the first bonding layer 212 and the second bonding layer 222 are in direct contact with each other.

In the present embodiment, the first semiconductor substrate 210 and the second semiconductor substrate 220 may be automatically aligned through van der Waals bonds formed between water molecules and silanol groups at the two opposing oxide surfaces which are created by surface pre-conditioning using, for example, plasma and water wetting.

As illustrated in FIG. 2, in the present embodiment, the first base 211, the first patterned-conductive layers 214 and 214′ and the first conductive vias 217 may constitute a laminate substrate. The first base 211 may also be formed of a material including silicon, glass, etc. When a transparent interposer such as a glass interposer is used, the laser's energy can be directed to pass through the glass without significant absorption and to heat the solder directly, and/or be directed at and be absorbed by a non-transparent substrate such as a silicon substrate (or other substrates such as silicon carbide and gallium nitride) and converted into a local heat source for bonding.

As illustrated in FIG. 2, the first patterned-conductive layer 214 and 214′ are formed on two sides of the first base 211. Each of the first patterned-conductive layer 214 and 214′ is, for example, a build-up layer or a RDL layer including at least one trace (not illustrated), at least one dielectric layer (not illustrated) and/or conductive via (not illustrated). The first conductive vias 217 are formed within the first base 211 and electrically connect the first patterned-conductive layers 214 and 214′. The first conductive via 217 is, for example, a plated through hole, a through silicon via (TSV) or a through glass via.

In addition, the first bonding layer 212, the first conductive contact 213, the first conductive layer 215 and the first barrier/seed layer 216 include features (for example, structure, size and/or connection schemes) the same as or similar to those of the first bonding layer 112, the first conductive contact 113, the first conductive layer 115 and the first barrier/seed layer 116.

In comparison with the second semiconductor substrate 120 of FIG. 1, the second semiconductor substrate 220 of the present embodiment includes a first structure set and a second structure set, wherein the first structure set includes the second bonding layers 222, the second conductive contact 223, the second patterned-conductive layer 224, the second conductive layer 225 and the second barrier/seed layer 226, and the second structure set includes the second bonding layers 222′, the second conductive contact 223′, the second patterned-conductive layer 224′, the second conductive layer 225′ and the second barrier/seed layer 226′. The first structure set and the second structure set are formed on opposite two sides of the second base 221.

As illustrated in FIG. 2, in the present embodiment, the second base 221, the second patterned-conductive layers 224 and 224′ and the second conductive vias 227 may constitute an interposer, whether it be based on silicon, glass or other types of materials, or a laminate substrate. The second base 221 can be a silicon base, for example, a portion of a silicon wafer. The second patterned-conductive layers 224 and 224′ are formed on opposite two sides of the second base 221. Each of the second patterned-conductive layers 224 and 224′ is, for example, a RDL, a BEOL layer, a buildup layer or combination thereof. The second conductive vias 227 are formed within the second base 221 and electrically connect the second patterned-conductive layers 224 and 224′. The second conductive via 227 can be, for example, TSV.

As illustrated in FIG. 2, the second bonding layer 222, the second conductive contact 223, the second conductive layer 225 and the second barrier/seed layer 226 include the features (for example, structure, size and/or connection schemes) the same as or similar to those of the second bonding layer 122, the second conductive contact 123, the second conductive layer 125 and the second barrier/seed layer 126. In addition, the second bonding layer 222′, the second conductive contact 223′, the second conductive layer 225′ and the second barrier/seed layer 226′ include features (for example, structure, size and/or connection schemes) the same as or similar to those of the second bonding layer 222, the second conductive contact 223, the second conductive layer 225 and the second barrier/seed layer 226.

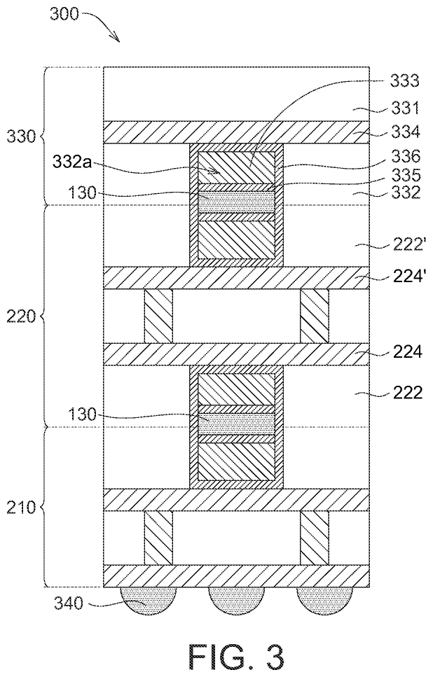

Referring to FIG. 3, FIG. 3 illustrates a schematic diagram of a cross-sectional view of a semiconductor device 300 according to an embodiment of the invention. The semiconductor device 300 includes the first semiconductor substrate 210, the second semiconductor substrate 220, a third semiconductor substrate 330, at least one solder 130 and at least one solder ball 340.

As illustrated in FIG. 3, the third semiconductor substrate 330 includes a third base 331, a third bonding layer 332, at least one third conductive contact 333, a third patterned-conductive layer 334, a third conductive layer 335 and a third barrier/seed layer 336. The third base 331, the third bonding layer 332, the third conductive contact 333, the third patterned-conductive layer 334, the third conductive layer 335 and the third barrier/seed layer 336 include features the same as or similar to those of the second base 121, the second bonding layer 122, the second conductive contact 123, the second patterned-conductive layer 124, the second conductive layer 125 and the second barrier/seed layer 126, and the similarities will not be repeated here.

As illustrated in FIG. 3, the third bonding layer 332 has at least one third through via 332a. The third conductive contact 333 is formed within the third through via 332a. The third bonding layer 332 of the third semiconductor substrate 330 and the second bonding layer 222′ of the second semiconductor substrate 220 are in direct contact with each other.

In the present embodiment, the first semiconductor substrate 210 and the second semiconductor substrate 220 may be automatically aligned through van der Waals bonds formed between water molecules and silanol groups at the two opposing oxide surfaces which are created by surface pre-conditioning using, for example, plasma and water wetting.

Similarly, the second semiconductor substrate 220 and the third semiconductor substrate 330 may be automatically aligned through t van der Waals bonds formed between water molecules and silanol groups at the two opposing oxide surfaces which are created by surface pre-conditioning using, for example, plasma and water wetting.

As illustrated in FIG. 3, the solder balls 340 are formed on the first semiconductor substrate 210. As a result, the semiconductor device 300 may be mounted on a substrate (for example, a printed circuit board (PCB)) through the solder balls 340.

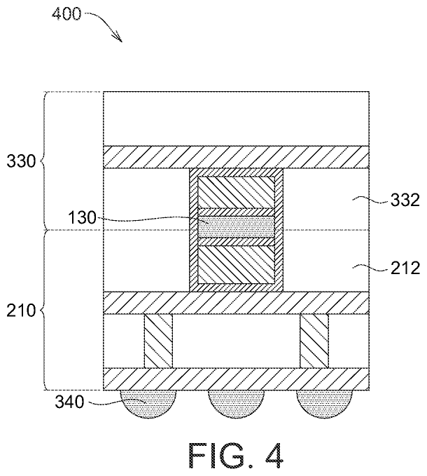

Referring to FIG. 4, FIG. 4 illustrates a schematic diagram of a cross-sectional view of a semiconductor device 400 according to an embodiment of the invention. The semiconductor device 400 includes the first semiconductor substrate 210, the third semiconductor substrate 330, at least one solder 130 and at least one solder ball 340.

In the present embodiment, the first bonding layer 212 of the first semiconductor substrate 210 and the third bonding layer 322 of the third semiconductor substrate 320 are in direct contact with each other. The first semiconductor substrate 210 and the third semiconductor substrate 330 are automatically aligned through van der Waals bonds formed between water molecules and silanol groups at the two opposing oxide surfaces which are created by surface pre-conditioning using, for example, plasma and water wetting.

As illustrated in FIG. 4, the solder balls 340 are formed on the first semiconductor substrate 210. As a result, the semiconductor device 400 may be mounted on a substrate through the solder balls 340.

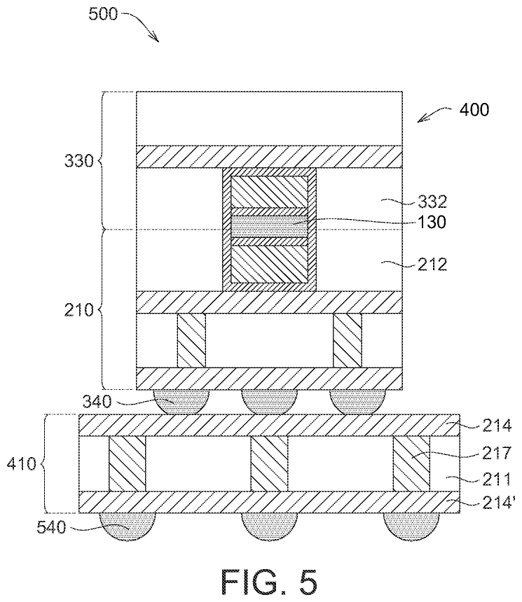

Referring to FIG. 5, FIG. 5 illustrates a schematic diagram of a cross-sectional view of a semiconductor device 500 according to an embodiment of the invention. The semiconductor device 500 includes the first semiconductor substrate 210, the third semiconductor substrate 330, at least one solder 130, at least one solder ball 340, a substrate 410 and at least one solder ball 540.

As illustrated in FIG. 5, in the present embodiment, the first bonding layer 212 of the first semiconductor substrate 210 and the third bonding layer 322 of the third semiconductor substrate 320 are in direct contact with each other. In addition, the first semiconductor substrate 210 and the third semiconductor substrate 330 are automatically aligned through van der Waals bonds formed between water molecules and silanol groups at the two opposing oxide surfaces which are created by surface pre-conditioning using, for example, plasma and water wetting.

As illustrated in FIG. 5, the semiconductor device 400 is mounted on the substrate 410 through the solder balls 340. Furthermore, the solder balls 340 are formed between the second semiconductor substrate 210 and the substrate 410 for electrically connecting the second semiconductor substrate 210 and the substrate 410.

As illustrated in FIG. 5, the solder balls 540 are formed on the substrate 410. As a result, the semiconductor device 500 may be mounted on a substrate (for example, a PCB) through the solder balls 540.

As illustrated in FIG. 5, the substrate 410 may be a laminate substrate or an interposer. The substrate 410 includes the first base 211, the first patterned-conductive layer 214, the first patterned-conductive layer 214′ and at least one first conductive via 217. The first base 211 may be formed of a material including silicon, glass, etc. The first patterned-conductive layer 214 and 214′ are formed on two sides of the first base 211. The first conductive vias 217 are formed within the first base 211 and electrically connect the first patterned-conductive layers 214 and 214′. The first conductive via 217 is, for example, a plated through hole, a TSV or a through glass via.

In another embodiment, the semiconductor device 500 may omit the third semiconductor substrate 330.

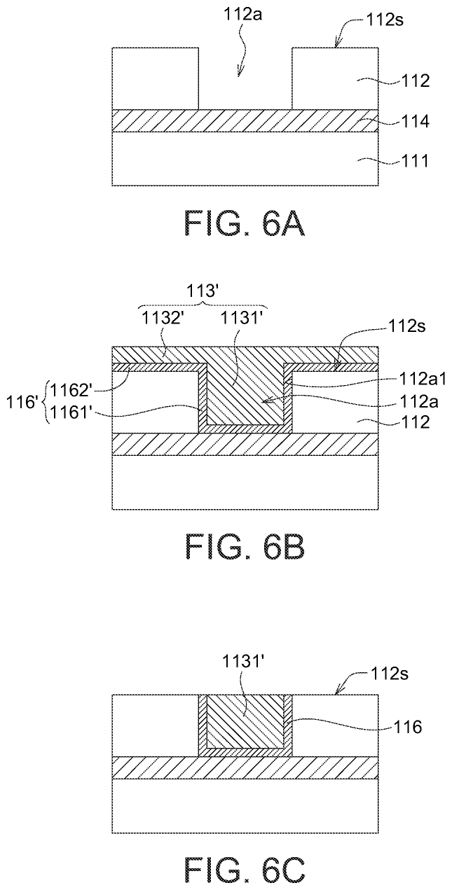

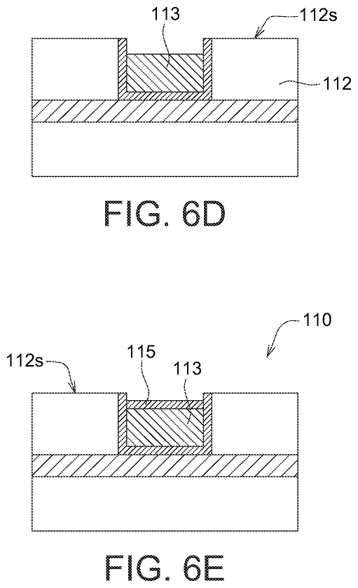

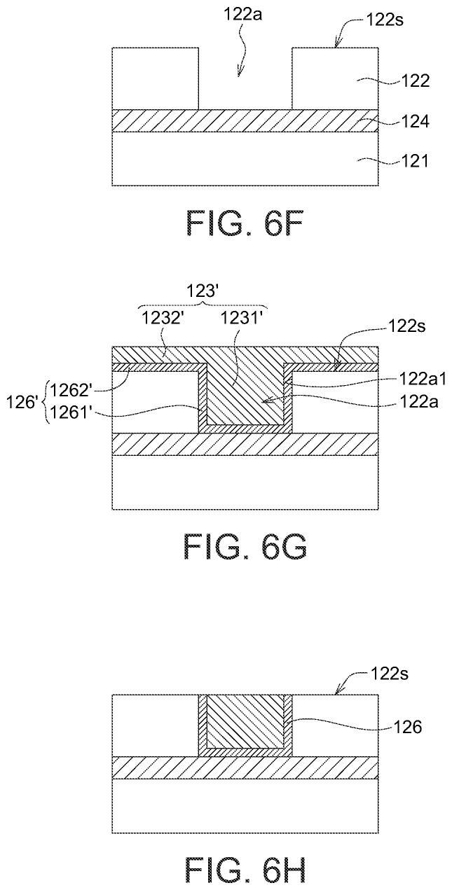

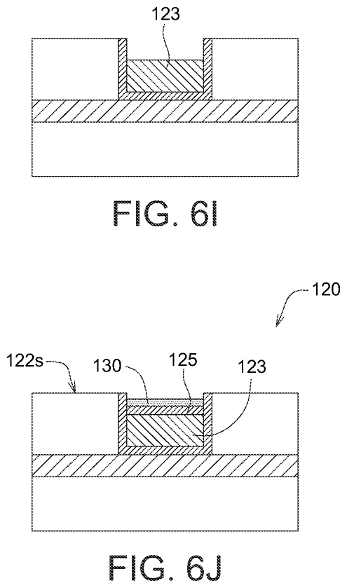

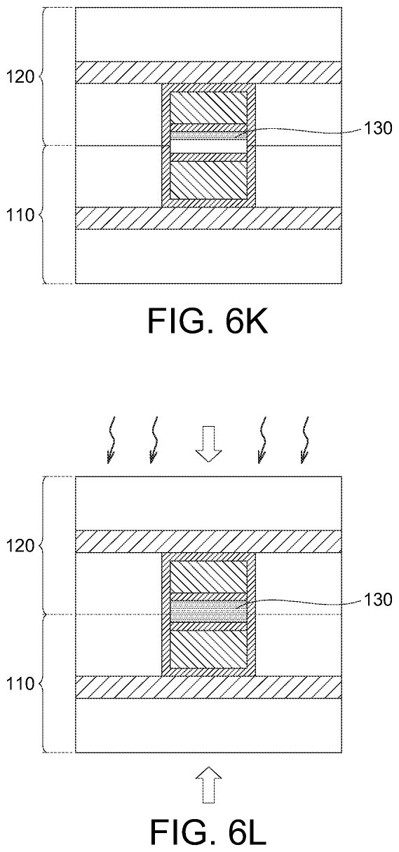

FIGS. 6A to 6L illustrate schematic diagrams of a manufacturing method of the semiconductor device 100 of FIG. 1.

The first semiconductor substrate 110 is prepared. The manufacturing method of the first semiconductor substrate 110 includes the following steps as illustrated in FIGS. 6A to 6E.

As illustrated in FIG. 6A, the first bonding layer 112 is formed over the first base 111, wherein the first bonding layer 112 has at least one first through via 112a. The first through via 112a is recessed with respect to a first bonding surface 112s of the first bonding layer 112 and may be formed using, for example, photolithography, etching, laser ablation, etc.

Then, the first conductive contact 113 of FIG. 1 may be formed within the first through via 112a, as illustrated in FIGS. 6B to 6D.

Furthermore, as illustrated in FIGS. 6B, the first barrier/seed layer material 116′ is formed on the first through via 112a using, for example, vapor deposition, plating, etc. The first barrier/seed layer material 116′ includes a first portion 1161′ and a second portion 1162′, wherein the first portion 1161′ is formed on a lateral sidewall 112a1 of the first through via 112a, and the second portion 1162′ covers the first bonding surface 112s of the first bonding layer 112. Then, a first conductive contact material 113′ is formed using, for example, plating, etc. The first conductive contact material 113′ includes a first portion 1131′ and a second portion 1132′, wherein the first portion 1131′ fills the first through via 112a, and the second portion 1132′ covers the second portion 1162′ of the first barrier/seed layer material 116′.

As illustrated in FIG. 6C, a portion of the first conductive contact material 113′ and a portion of the first barrier/seed layer material 116′ are removed using CMP (chemical mechanical polishing), etching, etc. Furthermore, the second portion 1132′ of the first conductive contact material 113′ and the second portion 1162′ of the first barrier/seed layer material 116′ are removed. After overburden layers removal, the formed first bonding surface 112s is a planarized surface, the first barrier/seed layer 116 is formed.

As illustrated in FIG. 6D, the first conductive contact 113 is recessed from the first bonding surface 112s as a result of the above overburden layers removal step.

As illustrated in FIG. 6E, the first conductive layer 115, which can be a barrier layer or barrier/bonding layers is formed on the first conductive contact 113 using, for example, plating, vapor deposition, photolithography, etching, photoresist removal, etc.

Then, the first bonding surface 112s (SiO₂) of the first bonding layer 112 may be pre-cleaned with a piranha solution (H₂SO₄/H₂O₂/H₂O), and be activated with N₂ plasma using, for example, a sputtering system such as SH-550 from ULVAC at a power of 180 W for 1 min followed by wetting the first bonding surface 112s of the first bonding layer 112 with a de-ionized water. For example, a small amount (about 1 microliter) of de-ionized water is dispensed on the activated first bonding surface 112s. A first hydrophilic structure (not illustrated) is formed on the first bonding surface 112s of the first bonding layer 112 after wetting the first bonding surface 112s of the first bonding layer 112. So far, the first semiconductor substrate 110 is formed. In general, pre-bonding surface pre-conditioning of the two substrates to be bonded can involve:
Chemical mechanical polish (CMP) to achieve, preferably a surface roughness, RA (arithmetic average roughness)<1 or 0.5 nm for both substrates (this level of RA can be achieved by CMP),
Wet surface pre-treatments involving ultrasonic de-ionized (DI) water clean, H₂SO₄/H₂O₂ treatment, NH₃/H₂O₂ treatment, and N₂ blow dry, and/or
Plasma/inductively coupled plasma reactive ion etching (ICP-RIE)—O₂, N₂, H₂/O₂, deep RIE (DRIE)—O₂/CF₄, and/or activation of the bonding surfaces by a fast atom beam gun, FAB (using, for instance, argon neutral atom beam at ˜1 keV), or by an ion gun (using for instance, argon ion at ˜60 eV) to remove oxide films in vacuum and to reveal dangling bonds at the surfaces for bonding.

Then, the second semiconductor substrate 120 is prepared. The manufacturing method of the second semiconductor substrate 120 includes the following steps as illustrated in FIGS. 6F to 6J.

As illustrated in FIG. 6F, the second bonding layer 122 is formed over the second base 121, wherein the second bonding layer 122 has at least one second through via 122a. The second through via 122a is recessed with respect to a second bonding surface 122s of the second bonding layer 122 and may be formed using, for example, photolithography, etching, laser ablation, etc.

Then, the second conductive contact 123 of FIG. 1 may be formed within the second through via 122a, as illustrated in FIGS. 6G to 6I.

Furthermore, as illustrated in FIG. 6G, the second barrier/seed layer material 126′ is formed on the second through via 122a using, for example, vapor deposition, plating, etc. The second barrier/seed layer material 126′ includes a first portion 1261′ and a second portion 1262′, wherein the first portion 1261′ is formed on a lateral sidewall 122a1 of the second through via 122a, and the second portion 1262′ covers the second bonding surface 122s of the second bonding layer 122. Then, a second conductive contact material 123′ is formed by using, for example, plating, etc. The second conductive contact material 123′ includes a first portion 1231′ and a second portion 1232′, wherein the first portion 1231′ fills the second through via 122a, and the second portion 1232′ covers the second portion 1262′ of the second barrier/seed layer material 126′.

As illustrated in FIG. 6H, a portion of the second conductive contact material 123′ and a portion of the second barrier/seed layer material 126′ are removed using, for example, CMP, etching, etc. Furthermore, the second portion 1132′ of the second conductive contact material 123′ and the second portion 1262′ of the second barrier/seed layer material 116′ are removed. After overburden layers removal, the formed second bonding surface 122s is a planarized surface, the second barrier/seed layer 126 is formed and, as illustrated in FIG. 6I, the second conductive contact 123 can be recessed as needed from the second bonding surface 122s.

As illustrated in FIG. 6J, the second conductive layer 125 is formed on the second conductive contact 123 using, for example, plating, vapor deposition, photolithography, etching, photoresist removal, etc. Then, the solder 130 is formed on the second conductive layer 125 within the second through via 122a.

Then, the second bonding surface 122s (SiO₂ surface) of the second bonding layer 122 may be pre-cleaned with the piranha solution (H₂SO₄/H₂O₂/H₂O), and be activated with N₂ plasma using, for example, a sputtering system such as SH-550 from ULVAC at a power of 180 W for 1 min, followed by wetting the second bonding surface 122s of the second bonding layer 122 with a de-ionized water. For example, a small amount (about 1 microliter) of de-ionized water is dispensed on the activated second bonding surface 122s. A second hydrophilic structure (not illustrated) is formed on the second bonding surface 122s of the second bonding layer 122 after wetting the second bonding surface 122s of the second bonding layer 122. So far, the second semiconductor substrate 120 is formed. In general, pre-bonding surface pre-conditioning of the two substrates to be bonded can involve:
Chemical mechanical polish (CMP) to achieve, preferably a surface roughness, RA (arithmetic average roughness)<1 or 0.5 nm for both substrates (this level of RA can be achieved by CMP),
Wet surface pre-treatments involving ultrasonic de-ionized (DI) water clean, H₂SO₄/H₂O₂ treatment, NH₃/H₂O₂ treatment, and N₂ blow dry, and/or
Plasma/inductively coupled plasma reactive ion etching (ICP-RIE)—O₂, N₂, H₂/O₂, deep RIE (DRIE)—O₂/CF₄, and/or activation of the bonding surfaces by a fast atom beam gun, FAB (using, for instance, argon neutral atom beam at ˜1 keV), or by an ion gun (using for instance, argon ion at ˜60 eV) to remove oxide films in vacuum and to reveal dangling bonds at the surfaces for bonding.

As illustrated in FIG. 6K, the first semiconductor substrate 110 and the second semiconductor substrate 120 are brought into direct contact with each other. The first semiconductor substrate 110 and the second semiconductor substrate 120 are automatically aligned and pre-bonded at low temperatures such as room temperature through the hydrophilic layers formed on the surfaces of the bonding layers after water wetting on two opposing oxide surfaces.

Furthermore, as illustrated in FIG. 6L, the first bonding layer 112 and the second bonding layer 122 are heated using laser assisted bonding (with the use of, for example, an IR laser) and the bonding stage as needed at low temperatures. IR laser may irradiate the two substrates 110 and 120 or one of the two substrates to heat and anneal the substrates to form permanent dielectric-to-dielectric covalent bond and also to melt and reflow the solder and bond the solder/barrier coated conductive contact of one substrate to the barrier/bonding layer coated conductive contact of another substrate under ambient conditions, in a nitrogen atmosphere or in vacuum. Following IR laser assisted bonding, the two substrates can be further heated as needed. In addition, a pressure may be applied to the first bonding layer 112 and the second bonding layer 122 to facilitate solder bonding and direct dielectric to-dielectric bonding.

For Infrared (IR) laser assisted soldering and direct bonding utilized for the ultrafine pitch application, diode lasers at a wavelength in the near IR spectrum (e.g., 980 nm or 940 nm) are favored in comparison with other IR laser sources such as carbon dioxide (CO₂) and Nd:YAG lasers because diode lasers offers high efficiency, long service life, compact size, ease of integration into existing bonding stations and low maintenance. The most popular wavelengths of commercially available diode lasers range from 810 nm to 980 nm although their wavelengths may range from 630 nm to 1900 nm. CO₂ lasers produce IR light with 10,600 nm wavelength, which is highly absorptive in organic materials such as IC laminate substrates and printed circuit boards and are therefore not ideal for laser assisted bonding which inadvertently will involve organic substrates. Nd:YAG lasers operate in the IR spectrum at 1064 nm wavelength. Compared to CO₂ lasers operating in high wavelength spectrum, the near IR spectrum offered by diode and Nd:YAG lasers is less absorbent on organic materials and less reflective off metal surfaces and is therefore better suited for laser assisted flip chip assembly.

Direct oxide-to-oxide bonding (for ultrafine pitches) proceeds in the following process sequence: (1) formation of dangling bonds and bonding between hydroxyl groups and water molecules through plasma activation using gases such as O₂ (oxygen)/N₂ (nitrogen)/Ar (argon); (2) bonding of wafers (or chip and wafer) with oxide bonding layers at room temperature and atmospheric pressure via van der Waals hydrogen bonds between two to three monolayers of water molecules and polar hydroxyl (OH) groups (which terminate at both the native and thermal SiO₂ surfaces); (3) formation of van der Waals bonds between H₂O molecules and silanol groups (Si—OH—(H₂O)x-HO—Si; silanol group ═Si—OH) on wafer surfaces; and (4) annealing to remove water molecules at the interface and form covalent bonds at temperatures typically less than 300° C. For oxide-to-oxide bonding, one can vary oxide type and deposition technique, process conditions such as plasma gas, plasma power, surface roughness pertaining to chemical mechanical polish (CMP), surface cleanliness, mono- to multiple layers of water molecules from de-ionized cleaning, bonding conditions (such as temperature and speed), and anneal conditions (e.g., anneal temperatures, anneal time and number of annealing steps) to achieve good bonding quality and high shear strength. Void formation caused by water droplet formation (the Joule-Thomason expansion effect) at wafer edge in the case of W2W bonding during direct bonding can be avoided by controlling key parameters such as plasma conditions, surface roughness, degree of cleanliness, wafer warpage/flatness and bonding conditions. When needed, oxide-to-oxide bonding can be performed on a platform or chuck having a flat central zone and an outer annular zone lower than the central zone with the edge portion of a mounted wafer biased towards the outer annular zone to disrupt the van der Waals forces (as stated above) at the outer annular zone. This approach creates an edge gap for water molecules to escape at wafer edge in the case of W2W assembly.

Besides SiO₂, the bonding or dielectric layer can also be a fully cured polyimide (PI), commonly used in wafer back-end-of-the-line (BEOL) and advanced SiP wafer-level processes. Take fully cured PI-to-fully cured PI bonding based on the pyromellitic dianhydride (PMDA) and 4,4′-diaminodiphenyl ether (4,4′-ODA) PI chemistry, for instance, one can achieve void-free PI-to-PI bonding by activating the PI surfaces by oxygen plasma activation to generate low-density hydrophilic groups on the PI surface which effectively enhances adsorption of water molecules introduced by the subsequent de-ionized water wetting process. A water based no-clean flux may be considered to replace deionized water wetting following plasma surface activation. The adsorbed water molecules, in turn, brings in considerable high-density OH (hydroxyl) groups which facilitate pre-bonding. Following PI-to-PI pre-bondong, PI-to-PI hybrid bonding can take place using IR laser assisted bonding and bonding stage as needed at temperatures preferably below 250° C. Key parameters to consider in order to achieve a bond include plasma activation time, volume of water introduced, bonding temperature, pressure and bonding time.

Oxide-to-oxide hybrid bonding requires high component flatness and surface cleanliness to avoid electrical interconnection fails due to silicon dioxide's high hardness and poor deformation characteristics. Compared to the conventional oxide-to-oxide hybrid bonding, PI-to-PI bonding allows for higher surface roughness and is more tolerant of component flatness due to the low modulus and more compliant characteristics of the PIs. Even though similar conductive via shapes are shown in FIG. 6L for the two semiconductor substrates 110 and 120, the vias can take on different shapes and geometries.

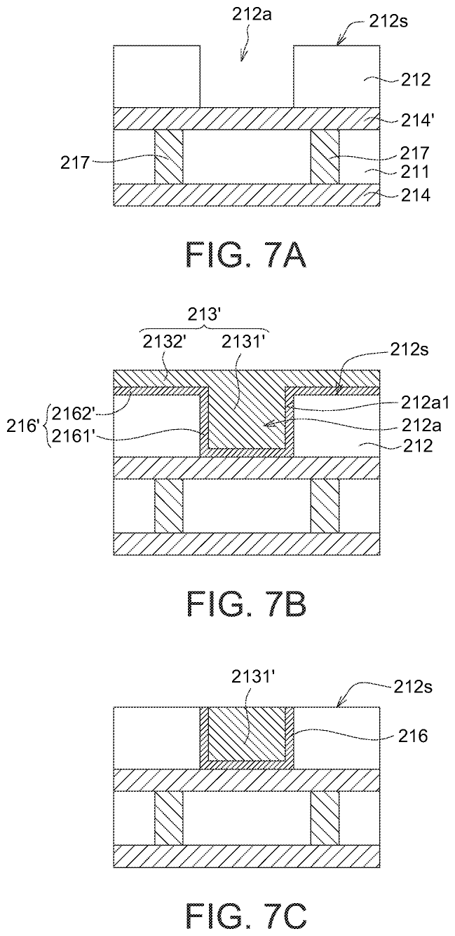

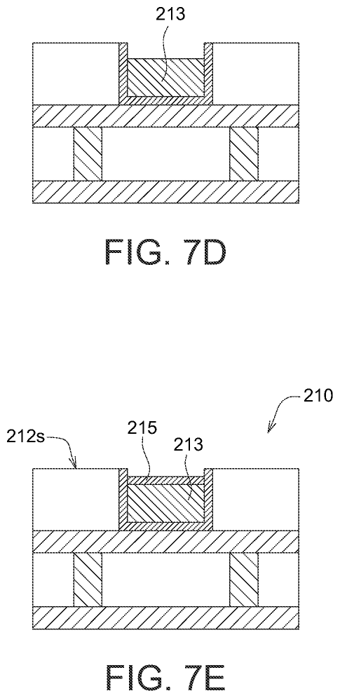

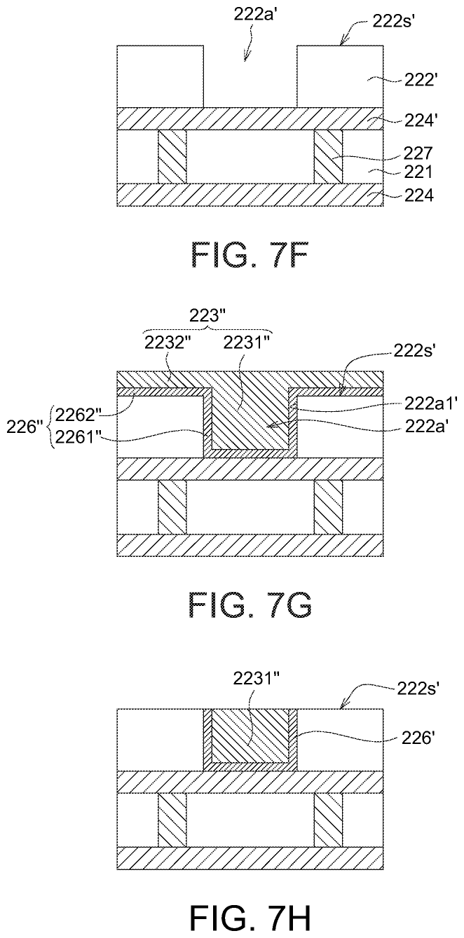

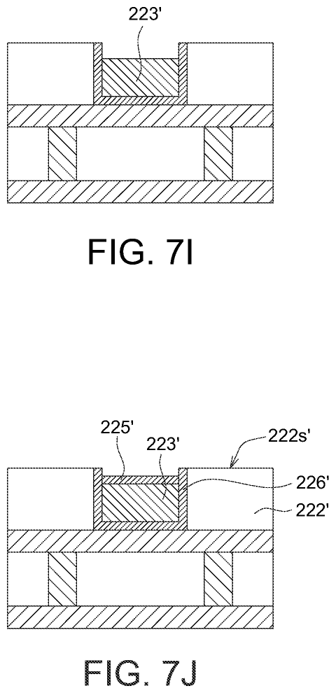

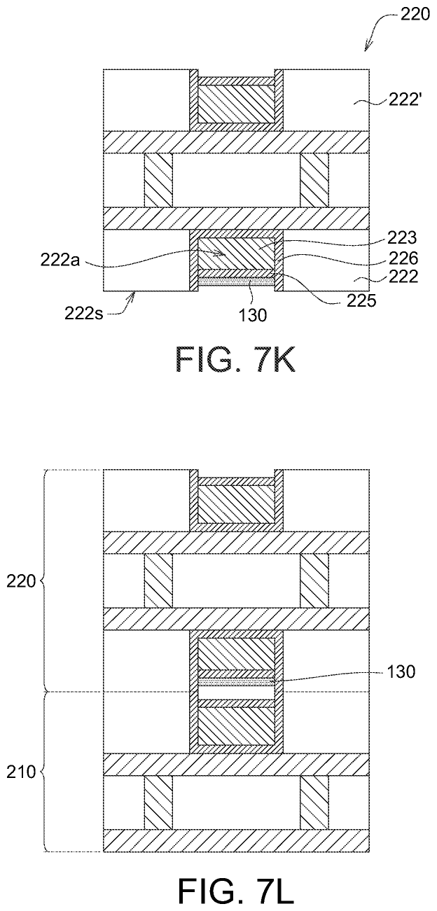

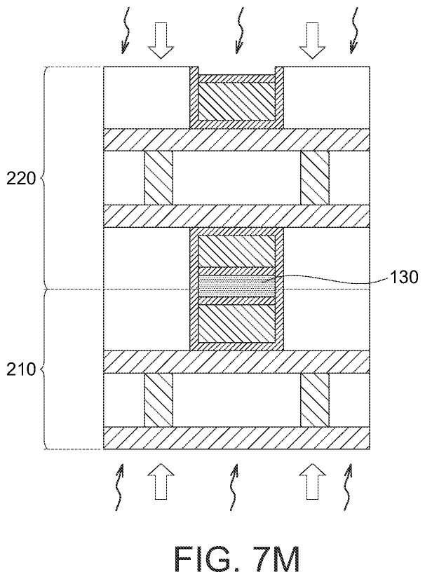

FIGS. 7A to 7M illustrate schematic diagrams of a manufacturing method of the semiconductor device 200 of FIG. 2.

The first semiconductor substrate 210 of FIG. 7E is prepared. The manufacturing method of the first semiconductor substrate 210 includes the following steps as illustrated in FIGS. 7A to 7E.

As illustrated in FIG. 7A, the first bonding layer 212 is formed over the first base 211, wherein the first bonding layer 212 has at least one first through via 212a. The first through via 212a is recessed with respect to a first bonding surface 212s of the first bonding layer 212 and may be formed using, for example, photolithography, etching, laser ablation, etc. In addition, the first patterned-conductive layer 214 and 214′ are formed on two sides of the first base 211. The first conductive vias 217 are formed within the first base 211 and electrically connect the first patterned-conductive layers 214 and 214′.

Then, the first conductive contact 213 is formed within the first through via 212a, as illustrated in FIGS. 7B to 7D.

Furthermore, as illustrated in FIG. 7B, the first barrier/seed layer material 216′ is formed on the first through via 212a using, for example, vapor deposition, plating, etc. The first barrier/seed layer material 216′ includes a first portion 2161′ and a second portion 2162′, wherein the first portion 2161′ is formed on a lateral sidewall 212a1 of the first through via 212a, and the second portion 2162′ covers the first bonding surface 212s of the first bonding layer 212. Then, a first conductive contact material 213′ is formed by using, for example, plating, etc. The first conductive contact material 213′ includes a first portion 2131′ and a second portion 2132′, wherein the first portion 2131′ fills the first through via 112a, and the second portion 2132′ covers the second portion 2162′ of the first barrier/seed layer material 216′.

As illustrated in FIG. 7C, a portion of the first conductive contact material 213′ and a portion of the first barrier/seed layer material 216′ are removed using, for example, CMP, etching, etc. Furthermore, the second portion 2132′ of the first conductive contact material 213′ and the second portion 2162′ of the first barrier/seed layer material 216′ are removed. After overburden layers removal removing, the formed first bonding surface 212s is a planarized surface, the first barrier/seed layer 216 is formed, and as illustrated in FIG. 7D, the first conductive contact 213 is recessed from the first bonding surface 212s.

As illustrated in FIG. 7E, the first conductive layer 215 is formed on the first conductive contact 213.

Then, the first bonding surface 212s (SiO₂ surface) of the first bonding layer 212 may be pre-cleaned with a piranha solution (H₂SO₄/H₂O₂/H₂O), and be activated with N₂ plasma using, for example, a sputtering system such as SH-550 from ULVAC at a power of 180 W for 1 min, followed by wetting the first bonding surface 212s of the first bonding layer 212 with a de-ionized water. For example, a small amount (about 1 microliter) of de-ionized water is dispensed on the activated first bonding surface 212s. A first hydrophilic structure (not illustrated) is formed on the first bonding surface 212s of the first bonding layer 212 after wetting the first bonding surface 212s of the first bonding layer 212. So far, the first semiconductor substrate 210 is formed. In general, pre-bonding surface pre-conditioning of the two substrates to be bonded can involve:
Chemical mechanical polish (CMP) to achieve, preferably a surface roughness, RA (arithmetic average roughness)<1 or 0.5 nm for both substrates (this level of RA can be achieved by CMP),
Wet surface pre-treatments involving ultrasonic de-ionized (DI) water clean, H₂SO₄/H₂O₂ treatment, NH₃/H₂O₂ treatment, and N₂ blow dry, and/or
Plasma/inductively coupled plasma reactive ion etching (ICP-RIE)—O₂, N₂, H₂/O₂, deep RIE (DRIE)—O₂/CF₄, and/or activation of the bonding surfaces by a fast atom beam gun, FAB (using, for instance, argon neutral atom beam at ˜1 keV), or by an ion gun (using for instance, argon ion at ˜60 eV) to remove oxide films in vacuum and to reveal dangling bonds at the surfaces for bonding.

Then, the second semiconductor substrate 220 is prepared. The manufacturing method of the second semiconductor substrate 220 includes the following steps as illustrated in FIGS. 7F to 7J.

As illustrated in FIG. 7F, the second bonding layer 222′ is formed over the second base 221, wherein the second bonding layer 222′ has at least one second through via 222a′. The second through via 222a′ is recessed with respect to a second bonding surface 222s′ of the second bonding layer 222′ and may be formed using, for example, photolithography, etching, laser ablation, etc. In addition, the second patterned-conductive layers 224 and 224′ are formed on two sides of the second base 221. The second conductive vias 227 are formed within the second base 221 and electrically connected to the second patterned-conductive layers 224 and 224′.

As illustrated in FIG. 7G, the second barrier/seed layer material 226″ is formed on the second through via 222a′ using, for example, vapor deposition, plating, etc. The second barrier/seed layer material 226″ includes a first portion 2261″ and a second portion 2262″, wherein the first portion 2261″ is formed on a lateral sidewall 222a1′ of the second through via 222a′, and the second portion 2262″ covers the second bonding surface 222s′ of the second bonding layer 222′. Then, a second conductive contact material 223″ is formed by using, for example, plating, etc. The second conductive contact material 223″ includes a first portion 2231″ and a second portion 2232″, wherein the first portion 2231″ fills the second through via 222a′, and the second portion 2232″ covers the second portion 2262″ of the second barrier/seed layer material 226″.

As illustrated in FIG. 7H, a portion of the second conductive contact material 223″ and a portion of the second barrier/seed layer material 226″ are removed using, CMP, etching, etc. Furthermore, the second portion 2132″ of the second conductive contact material 2232″ and the second portion 2262″ of the second barrier/seed layer material 216″ are removed. After overburden layers removal, the formed second bonding surface 222s′ is a planarized surface, the second barrier/seed layer 226′ is formed, and as illustrated in FIG. 7I, the second conductive contact 223′ is recessed.

As illustrated in FIG. 7J, the second conductive layer 225′ is formed on the second conductive contact 223′.

As illustrated in FIG. 7K, the second bonding layer 222, the second conductive contact 223 and the second barrier/seed layer 216 are formed by using processes the same as or similar to those of the second bonding layer 222′, the second conductive contact 223′ and the second barrier/seed layer 226′, and will not be repeated here. Then, the solder 130 is formed on the second conductive layer 225 within the second through via 222a.

Thereafter, the second bonding surface 222s (SiO₂ surface) of the second bonding layer 222 may be pre-cleaned with the piranha solution (H₂SO₄/H₂O₂/H₂O), and be activated with N₂ plasma using, for example, a sputtering system such as SH-550 from ULVAC at a power of 180 W for 1 min, followed by wetting the second bonding surface 222s of the second bonding layer 222 with a de-ionized water. For example, a small amount (about 1 microliter) of de-ionized water is dispensed on the activated second bonding surface 222s. A second hydrophilic structure (not illustrated) is formed on the second bonding surface 222s of the second bonding layer 222 after wetting the second bonding surface 222s of the second bonding layer 222. So far, the second semiconductor substrate 220 is formed. In general, pre-bonding surface pre-conditioning of the two substrates to be bonded can involve:
Chemical mechanical polish (CMP) to achieve, preferably a surface roughness, RA (arithmetic average roughness)<1 or 0.5 nm for both substrates (this level of RA can be achieved by CMP),
Wet surface pre-treatments involving ultrasonic de-ionized (DI) water clean, H₂SO₄/H₂O₂ treatment, NH₃/H₂O₂ treatment, and N₂ blow dry, and/or
Plasma/inductively coupled plasma reactive ion etching (ICP-RIE)—O₂, N₂, H₂/O₂, deep RIE (DRIE)—O₂/CF₄, and/or activation of the bonding surfaces by a fast atom beam gun, FAB (using, for instance, argon neutral atom beam at ˜1 keV), or by an ion gun (using for instance, argon ion at ˜60 eV) to remove oxide films in vacuum and to reveal dangling bonds at the surfaces for bonding.

As illustrated in FIG. 7L, the first semiconductor substrate 210 and the second semiconductor substrate 220 are brought into direct contact with each other. The first semiconductor substrate 210 and the second semiconductor substrate 220 are automatically aligned and pre-bonded at, for instance, room temperature through van der Waals bonds formed between water molecules and silanol groups at the two opposing oxide surfaces which are created by surface pre-conditioning using, for example, plasma and water wetting.

Furthermore, as illustrated in FIG. 7M, the first bonding layer 212 and the second bonding layer 222 are heated using laser assisted bonding (for example, IR laser) and the bonding stage as needed at low temperatures under ambient conditions, in a nitrogen atmosphere or in vacuum. IR laser may irradiate the two substrates 210 and 220 or one of the two substrates to heat and anneal the substrates to form permanent dielectric-to-dielectric bond and also to melt and reflow the solder and bond the solder/barrier coated conductive contact of one substrate to the barrier/bonding layer coated conductive contact of another substrate. Following IR laser assisted bonding, the two substrates can be further heated as needed at temperatures preferably below 250° C. In addition, a pressure may be applied to the first bonding layer 212 and the second bonding layer 222 to facilitate solder bonding and direct dielectric to-dielectric bonding.

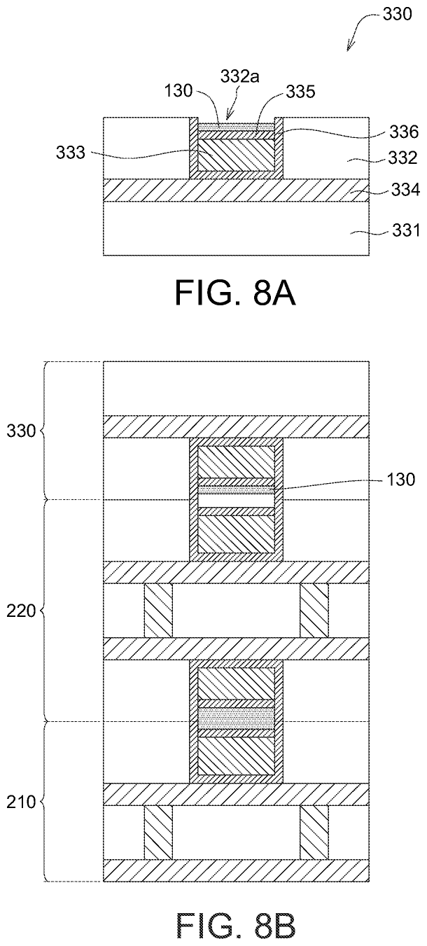

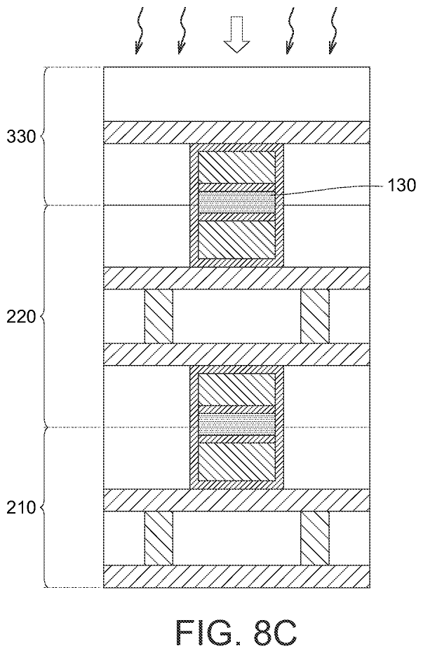

FIGS. 8A to 8C illustrate schematic diagrams of a manufacturing method of the semiconductor device 300 of FIG. 3.

As illustrated in FIG. 8A, the third semiconductor substrate 330 is prepared. The third semiconductor substrate 330 includes the third base 331, the third bonding layer 332, at least one third conductive contact 333, the third patterned-conductive layer 334, the third conductive layer 335 and the third barrier/seed layer 336. The solder 130 may be formed on the third conductive layer 335 within the third through via 332a.

The manufacturing method of the third semiconductor substrate 330 includes the steps the same as or similar to those of the second semiconductor substrate 120, as illustrated in FIG. 6F to 6J.

As illustrated in FIG. 8B, the first semiconductor substrate 210 and the second semiconductor substrate 220 are connected to each other. The connection method of the first semiconductor substrate 210 and the second semiconductor substrate 220 includes the steps the same as or similar to those of the first semiconductor substrate 210 or the second semiconductor substrate 220, as illustrated in FIG. 7L to 7M.

As illustrated in FIG. 8C, the third semiconductor substrate 330 and the second semiconductor substrate 220 are in direct contact with each other. The connection method of the second semiconductor substrate 220 and the third semiconductor substrate 330 includes the steps the same as or similar to those of the first semiconductor substrate 210 or the second semiconductor substrate 220.

Then, at least one the solder ball 340 is formed on the first semiconductor substrate 210 to form the semiconductor device 300 of FIG. 3.

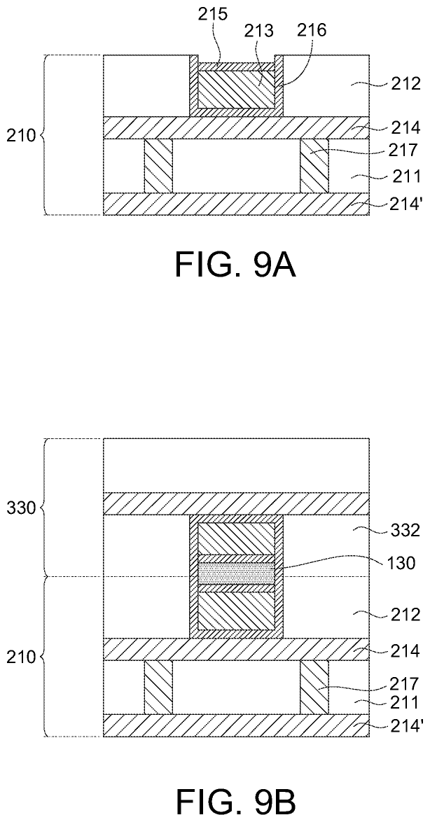

FIGS. 9A to 9B illustrate schematic diagrams of a manufacturing method of the semiconductor device 400 of FIG. 4.

As illustrated in FIG. 9A, the first semiconductor substrate 210 is prepared. As illustrated in FIG. 9B, the third semiconductor substrate 330 is prepared. Then, the third semiconductor substrate 330 and the first semiconductor substrate 210 are brought into direct contact with each other. The connection method of the first semiconductor substrate 210 and the third semiconductor substrate 330 includes the steps the same as or similar to those of the first semiconductor substrate 210 or the second semiconductor substrate 220. Then, at least one solder ball 340 is formed on the first patterned-conductive layer 214′ to form the semiconductor device 400 of FIG. 4.

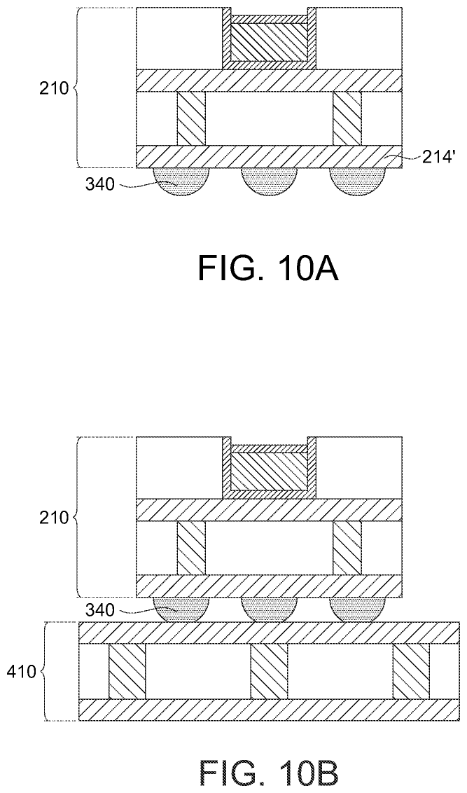

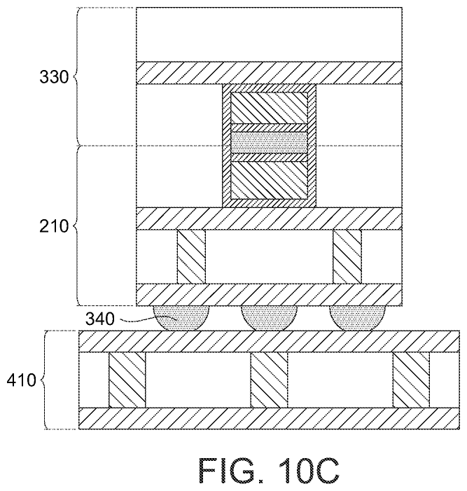

FIGS. 10A to 100 illustrate schematic diagrams of a manufacturing method of the semiconductor device 500 of FIG. 5.

As illustrated in FIG. 10A, the first semiconductor substrate 210 is prepared. Then, at least one solder ball 340 is formed on the first patterned-conductive layer 214′ of the first semiconductor substrate 210.

As illustrated in FIG. 10B, the structure of FIG. 10A is mounted on the substrate 410 through the solder balls 340.

As illustrated in FIG. 100, the third semiconductor substrate 330 is prepared. Then, the third semiconductor substrate 330 and the first semiconductor substrate 210 are in direct contact with each other. The connection method of the third semiconductor substrate 330 and the first semiconductor substrate 210 includes the steps the same as or similar to those of the first semiconductor substrate 210 or the second semiconductor substrate 220. So far, the semiconductor device 500 of FIG. 5 is formed.

To sum up, a semiconductor device, a semiconductor substrate and a manufacturing method thereof are provided, wherein a plurality of the semiconductor substrate are stacked to each other, and two adjacent semiconductor substrates are in direct contact with each other. In two stacked semiconductor substrates, one of the semiconductor substrates is, for example, one of a wafer substrate, a chip substrate, an interposer substrate or a laminate substrate, while another of the semiconductor substrates is, for example, a wafer substrate (which can be different from or the same as the first wafer substrate directly above), a chip substrate or a laminate substrate. In other words, the semiconductor device includes the following structure options: C2C (chip-to-chip) structure, C2S (Chip-to-Substrate) structure, C2W (Chip-to-Wafer) structure, W2W (Wafer-to-Wafer) structure, C2C2I (chip-to-chip-to-interposer) structure, and/or C2C2S (chip-to-chip-to-substrate) structure.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A semiconductor device, comprising:
a first semiconductor substrate comprising:
a first base;
a first bonding layer having a first through via; and
a first conductive contact formed within the first through via; and
a second semiconductor substrate comprising:
a second base;
a second bonding layer having a second through via; and
a second conductive contact formed within the second through via;
wherein the first conductive contact is electrically connected to the second conductive contact, and the first bonding layer and the second bonding layer are in direct contact with each other.

2. The semiconductor device as claimed in claim 1, wherein there is no adhesive layer between the first bonding layer and the second bonding layer.

3. The semiconductor device as claimed in claim 1, wherein the first bonding layer and the second bonding layer are formed of the same material.

4. The semiconductor device as claimed in claim 1, wherein the first base is silicon base, and the first semiconductor substrate further comprises a first patterned-conductive layer formed over the first base and exposed from the first through via.

5. The semiconductor device as claimed in claim 1, wherein the first semiconductor substrate further comprises a first patterned-conductive layer, and a first conductive via formed within the first base which is electrically connected to the first patterned-conductive layer.

6. The semiconductor device as claimed in claim 1, wherein the second semiconductor substrate further comprises:
two second patterned-conductive layers formed over two sides of the second base;
another second bonding layer wherein the second bonding layer and the another second bonding layer are formed over the two second patterned-conductive layers;
another second through via wherein the second through via and the another second through via are formed within the second bonding layer and the another second bonding layer, respectively;
another second conductive contact formed within the another second through via; and
a second conductive via electrically connecting the two second patterned-conductive layers.

7. The semiconductor device as claimed in claim 1, further comprises a third semiconductor substrate, comprising:
a third base;
a third bonding layer having a third through via; and
a third conductive contact formed within the third through via;
wherein the semiconductor substrate further comprises another second bonding layer, and the second bonding layer and the another second bonding layer are formed over two second patterned-conductive layers, respectively; and the third bonding layer and the another second bonding layer are in direct contact with each other.

8. The semiconductor device as claimed in claim 1, wherein the first semiconductor substrate comprises a first barrier layer formed on a first lateral surface of the first through via.

9. The semiconductor device as claimed in claim 1, further comprising a solder formed between the first conductive contact and the second conductive contact.

10. A semiconductor substrate, comprising:
a base;
a bonding layer having a bonding surface and a through via extending from the bonding surface; and
a conductive contact formed within the through via and recessed with respect to the bonding surface;
wherein the bonding surface is a planarized surface.

11. The semiconductor substrate as claimed in claim 10, further comprising:
a solder formed on the conductive contact.

12. A manufacturing method of a semiconductor device, comprises:
preparing a first semiconductor substrate, comprising:
forming a first bonding layer over a first base, wherein the first bonding layer has a first through via; and
forming a first conductive contact within the first through via;
preparing a second semiconductor substrate, comprising:
forming a second bonding layer over a second base, wherein the second bonding layer has a second through via; and
forming a second conductive contact within the second through via; and
the first bonding layer and the second bonding layer being in direct contact with each other.

13. The manufacturing method as claimed in claim 12, wherein before the first bonding layer and the second bonding layer are brought into direct contact with each other, the manufacturing method further comprises:
pre-cleaning a first bonding surface of the first bonding layer with a piranha solution; and
pre-cleaning a second bonding surface of the first bonding layer with the piranha solution.

14. The manufacturing method as claimed in claim 12, wherein before the first bonding layer and the second bonding layer being in direct contact with each other, the manufacturing method further comprises:
activating a first bonding surface of the first bonding layer with a plasma; and
activating a second bonding surface of the second bonding layer with the plasma.

15. The manufacturing method as claimed in claim 12, wherein, the manufacturing method further comprises:
wetting a first bonding surface of the first bonding layer with a de-ionized water; and
wetting a second bonding surface of the second bonding layer with the de-ionized water.

16. The manufacturing method as claimed in claim 15, wherein:
a first hydrophilic structure is formed on the first bonding surface of the first bonding layer after wetting the first bonding surface of the first bonding layer;
a second hydrophilic structure is formed on the second bonding surface of the second bonding layer after wetting the second bonding surface of the second bonding layer;
wherein the first bonding layer and the second bonding layer are automatically aligned through the first hydrophilic structure and the second hydrophilic structure.

17. The manufacturing method as claimed in claim 12, further comprising:
heating the first bonding layer and the second bonding layer by using infrared laser.

18. The manufacturing method as claimed in claim 17, further comprising:
electrically connecting the first conductive contact to the second conductive contact during the step of heating the first bonding layer and the second bonding layer.
